(19) United States
(12) Patent Application Publication
(10) Pub. No.: US 2025/0140650 A1
(43) Pub. Date: May 1, 2025

(54) VIA CONNECTION IN MIDDLE BEOL WIRING

(71) Applicant: INTERNATIONAL BUSINESS MACHINES CORPORATION, ARMONK, NY (US)

(72) Inventors: Brent A. Anderson, Jericho, VT (US); Nicholas Anthony Lanzillo, Wynantskill, NY (US); Albert M. Chu, Nashua, NH (US); David Wolpert, Poughkeepsie, NY (US); Ruilong Xie, Niskayuna, NY (US); Lawrence A. Clevenger, Saratoga Springs, NY (US)

(21) Appl. No.: 18/499,266

(22) Filed: Nov. 1, 2023

(51) Int. Cl. H01L 23/48; H01L 21/768; H01L 23/522; H01L 23/528

(52) U.S. Cl. CPC H01L 23/481; H01L 21/76898; H01L 23/5226; H01L 23/5283

(57) ABSTRACT

Embodiments of present invention provide a semiconductor structure. The semiconductor structure includes a first device layer on top of a backside back-end-of-line (BEOL) structure; a middle BEOL structure on top of the first device layer, the middle BEOL structure including multiple layers of small pitch wires and multiple layers of large pitch wires on top of the multiple layers of small pitch wires; a second device layer on top of the middle BEOL structure; a frontside BEOL structure on top of the second device layer; a first type via connection from the second device layer to the multiple layers of small pitch wires; and a second type and a third type via connection form the second device layer to the multiple layers of large pitch wires. A method of forming the same is also provided.

### BACKGROUND

The present application relates to manufacturing of semiconductor integrated circuits. More particularly, it relates to via connections from a secondary device level to middle back-end-of-line wiring and a method of forming the same.

As semiconductor industry moves towards smaller node, field-effect-transistors (FETs) are aggressively scaled to fit into reduced footprint or real estate. In addition to scaling in absolute size of each individual FET, multiple FETs may be stacked together in a 3D integration scheme and/or packaging process to further increase the density or the number of FETs or devices in a given size of chip estate.

For back-to-back stacked FETs, such as back-to-back stacked nanosheet FETs, it is essential that the stacked FETs, both at the top and at the bottom, are provided with sufficient capabilities for source/drain and gate contacts, signal routing and interconnect and/or power supplies. However, with traditional back-end-of-line (BEOL) structure that is usually formed above a device layer, it is far from sufficient for the normal operation of the FETs involved.

### SUMMARY

Embodiments of present invention provide a semiconductor structure. The semiconductor structure includes a first device layer on top of a backside back-end-of-line (BEOL) structure; a middle BEOL structure on top of the first device layer; a second device layer on top of the middle BEOL structure; and a frontside BEOL structure on top of the second device layer, where the middle BEOL structure includes multiple layers of small pitch wires; multiple layers of large pitch wires on top of the multiple layers of small pitch wires; and a first type via connection from the second device layer to the multiple layers of small pitch wires. By connecting through the first type via connection, the multiple layers of small pitch wires provide additional signal routing functionality to the second device layer.

In one embodiment, a pitch of the large pitch wires is greater than three times a pitch of the small pitch wires. In another embodiment, a height of one of the large pitch wires is greater than three times a height of one of the small pitch wires. The size and/or height of the large pitch wires ensures adequate functionality such as for power delivery or supply purpose.

In one embodiment, the first type via connection is a continuous via. In another embodiment, the first type via connection is a stacked via made of at least two connected vias.

According to one embodiment, the semiconductor structure further includes a second type via connection from the second device layer to the multiple layers of large pitch wires. In one embodiment, the first type via connection has an aspect ratio that is greater than four times an aspect ratio of the second type via connection. The multiple layers of large pitch wires provide additional power supply or delivery functionality to the second device layer.

According to another embodiment, the semiconductor structure further includes a third type via connection from the second device layer to the multiple layers of large pitch wires, wherein the third type via connection has an aspect ratio that is greater than two times the aspect ratio of the second type via connection. In one embodiment, the second type via connection and the third type via connection have a substantially same height. In another embodiment, the first type, the second type, and the third type via connection are made of a metal different from a material of the middle BEOL structure.

Embodiments of present invention provide a method of forming a semiconductor structure. The method includes forming a first device layer on top of a substrate; forming a middle back-end-of-line (BEOL) structure on top of the first device layer; forming a second device layer on top of the middle BEOL structure; forming a frontside BEOL structure on top of the second device layer; attaching a handling wafer onto the frontside BEOL structure and flipping the substrate upside-down; removing the substrate to expose a bottom surface of the first device layer; and forming a backside BEOL structure on top of the bottom surface of the first device layer.

In one embodiment, forming the middle BEOL structure includes forming multiple layers of small pitch wires on top of the first device layer; and forming multiple layers of large pitch wires on top of the multiple layers of small pitch wires.

In another embodiment, forming the second device layer further includes forming one or more first type via connections connecting the second device layer to the multiple layers of small pitch wires; and forming one or more second type via connections connecting the second device layer to the multiple layers of large pitch wires.

In yet another embodiment, the one or more first type via connections are made to have an aspect ratio that is greater than four times an aspect ratio of the one or more second type via connections.

In a further embodiment, forming the second device layer further includes forming one or more third type via connections connecting the second device layer to the multiple layers of large pitch wires, wherein the one or more third type via connections are made to have an aspect ratio that is greater than two times the aspect ratio of the one or more second type via connections.

In one embodiment, the one or more first type, one or more second type, and one or more third type via connections are made of a metal different from a material of the middle BEOL structure.

According to one embodiment, the method further includes forming one or more placeholders in the substrate before forming the middle BEOL structure and replacing the one or more placeholders with one or more backside contacts.

### BRIEF DESCRIPTION OF THE DRAWINGS

The present invention will be understood and appreciated more fully from the following detailed description of embodiments of present invention, taken in conjunction with accompanying drawings of which:

FIGS. 1-4 are demonstrative illustrations of cross-sectional views of a semiconductor structure according to several embodiments of present invention;

FIGS. 5A-5H are demonstrative illustrations of cross-sectional views of a semiconductor structure at different steps of manufacturing thereof according to embodiments of present invention;

FIGS. 6A-6C are demonstrative illustrations of cross-section views of a semiconductor structure according to one embodiment of present invention; and

FIG. 7 is a demonstrative illustration of a flow-chart of a method of manufacturing a semiconductor structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

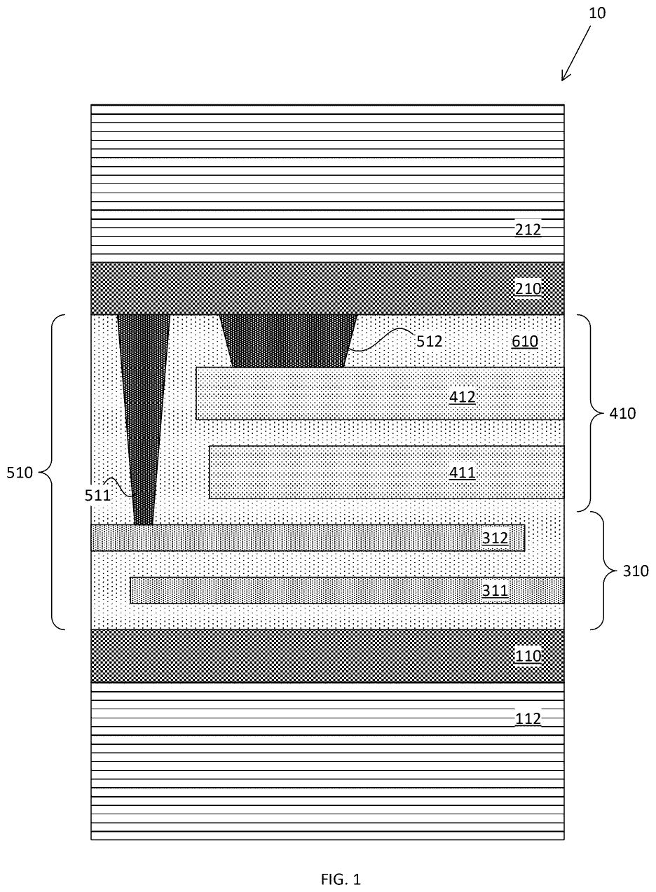

FIG. 1 is a demonstrative illustration of cross-sectional view of a semiconductor structure according to one embodiment of present invention. More specifically, embodiments of present invention provide a semiconductor structure 10 that includes a first device layer 110 on top of a backside back-end-of-line (BEOL) structure 112; a middle BEOL structure 510 on top of the first device layer 110; a second device layer 210 on top of the middle BEOL structure 510; and a frontside BEOL structure 212 on top of the second device layer 210. The first device layer 110 may be at a primary device level and the second device layer 210 may be at a secondary device level. In one embodiment, the backside BEOL structure 112 may a backside power distribution network (BSPDN) and may include one or more backside power rails (BSPRs) as well. One or more backside contacts may be formed between the first device layer 110 and the backside BEOL structure 112.

The middle BEOL structure 510 may be embedded in a dielectric layer 610 and may include multiple layers of small pitch wires 310 such as a first layer of small pitch wires 311 and a second layer of small pitch wires 312; and may include multiple layers of large pitch wires 410 formed on top of the multiple layers of small pitch wires 310. For example, the multiple layers of large pitch wires 410 may include a first layer of large pitch wires 411 and a second layer of large pitch wires 412. The small pitch wires may from time to time be referred to as tight pitch wires and the large pitch wires may from time to time be referred to as wide pitch wires.

Additionally, the middle BEOL structure 510 may include one or more first type via connection, such as a first type via connection 511 between the second device layer 210 and the multiple layers of small pitch wires 310. In other words, the first type via connection 511 may connect the second device layer 210 with one of the small pitch wires of the multiple layers of small pitch wires 310. In one embodiment, the first type via connection 511 may be a continuous via, meaning it is a single and tall via.

In one embodiment, the middle BEOL structure 510 may also include one or more second type via connection, such as a second type via connection 512, between the second device layer 210 and the multiple layers of large pitch wires 410. For example, the second type via connection 512 may connect the second device layer 210, such as one or more FETs in the second device layer 210, with one of the large pitch wires of the multiple layers of large pitch wires 410.

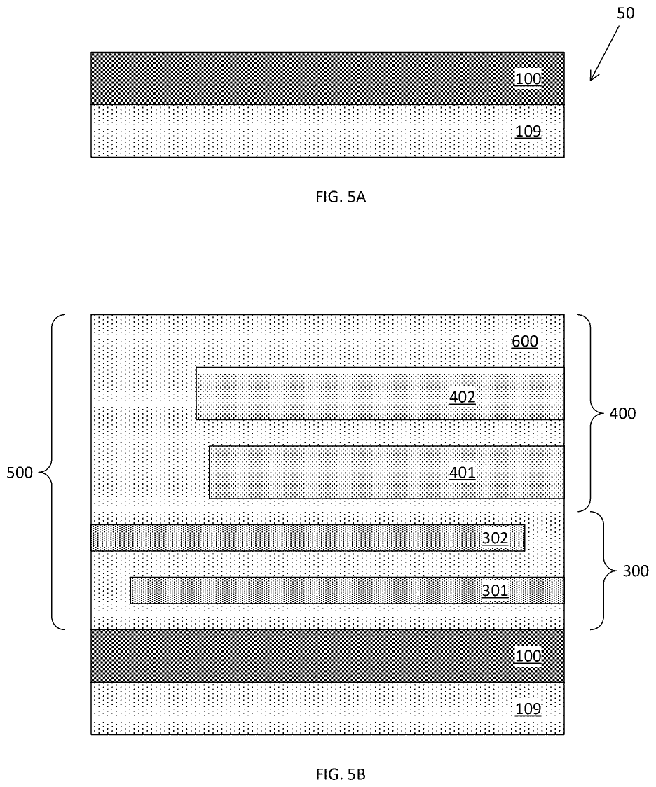

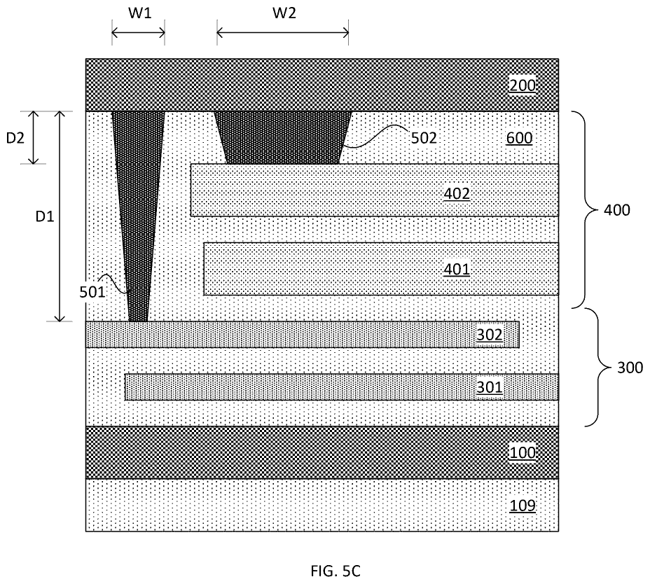

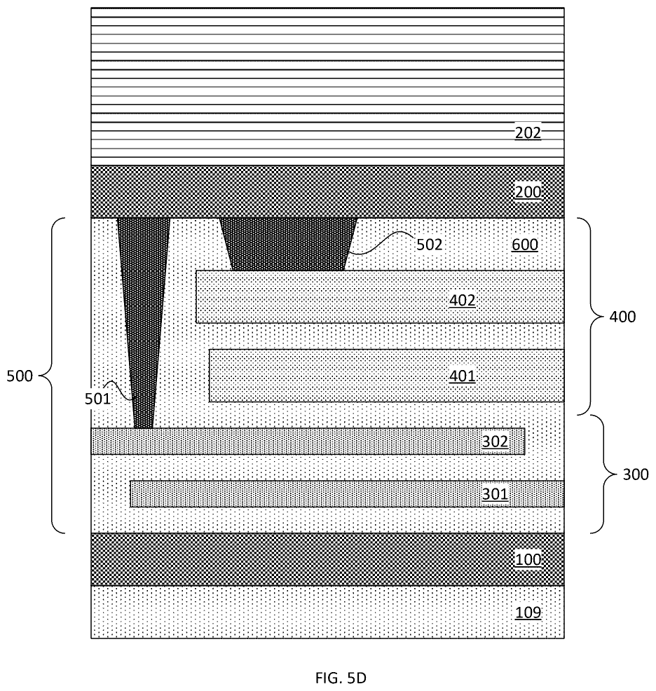

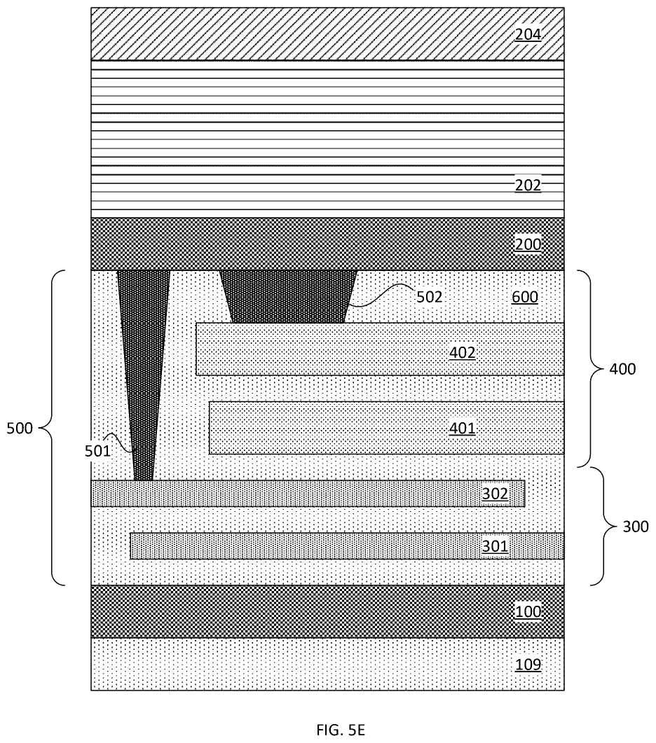

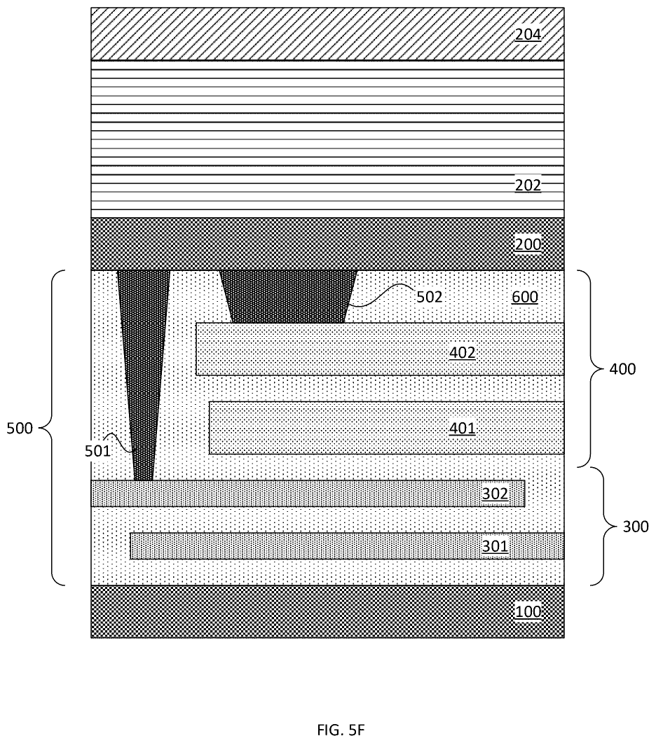

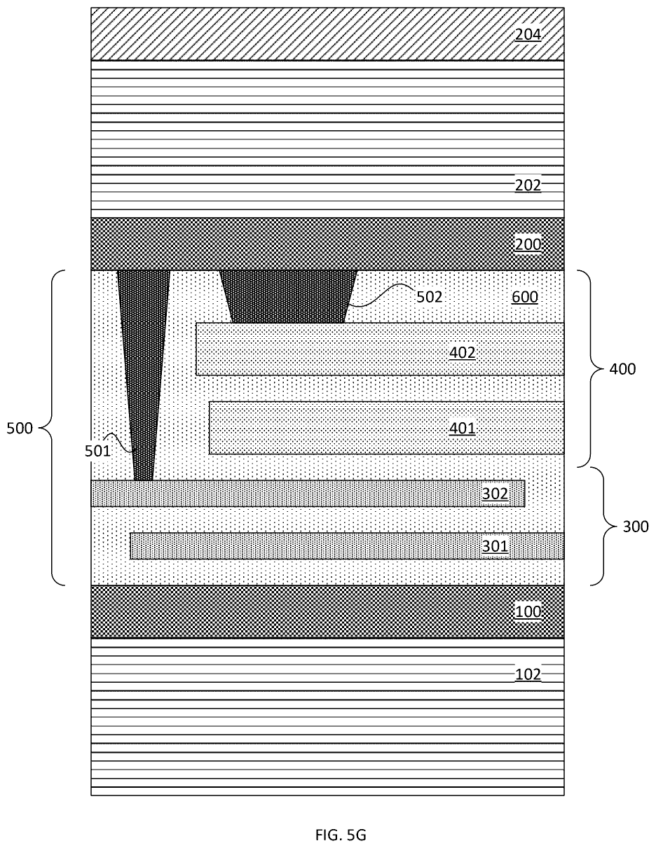

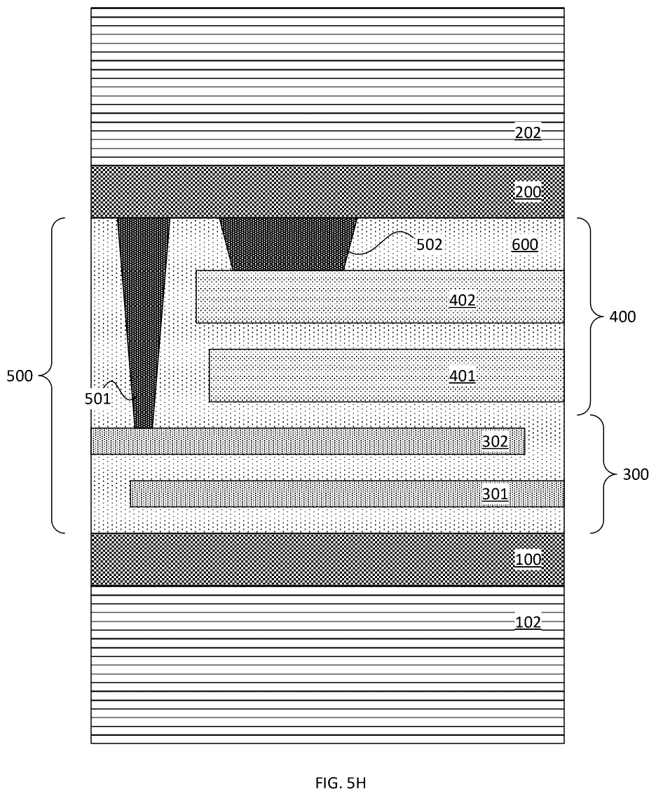

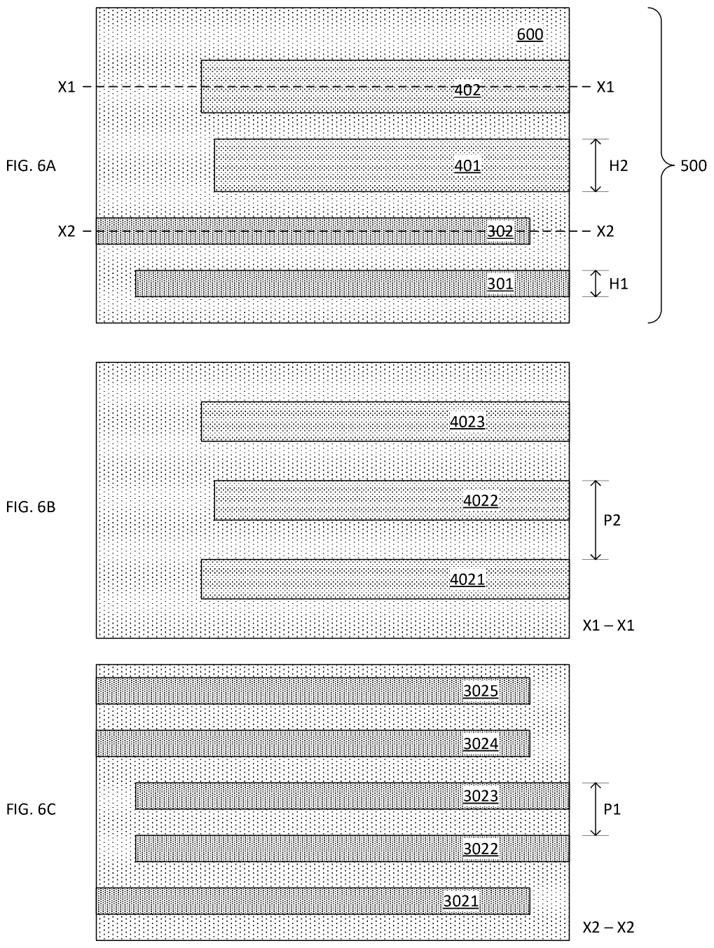

In one embodiment, the first type via connection 511 may have an aspect ratio that is greater than four times an aspect ratio of the second type via connection 512. The large pitch wires 411 and 412 may have a pitch that is greater than three times a pitch of the small pitch wires 311 and 312. The large pitch wires 411 and 412 may have a height that is greater than three times a height of the small pitch wires 311 and 312. More details are provided later in conjunction with the description of FIG. 5C, and FIGS. 6A-6C.

In another embodiment, the first type via connection 511 and the second type via connection 512 may be made of a metal that is different from a material of the multiple layers of small pitch wires 310 and the multiple layers of large pitch wires 410.

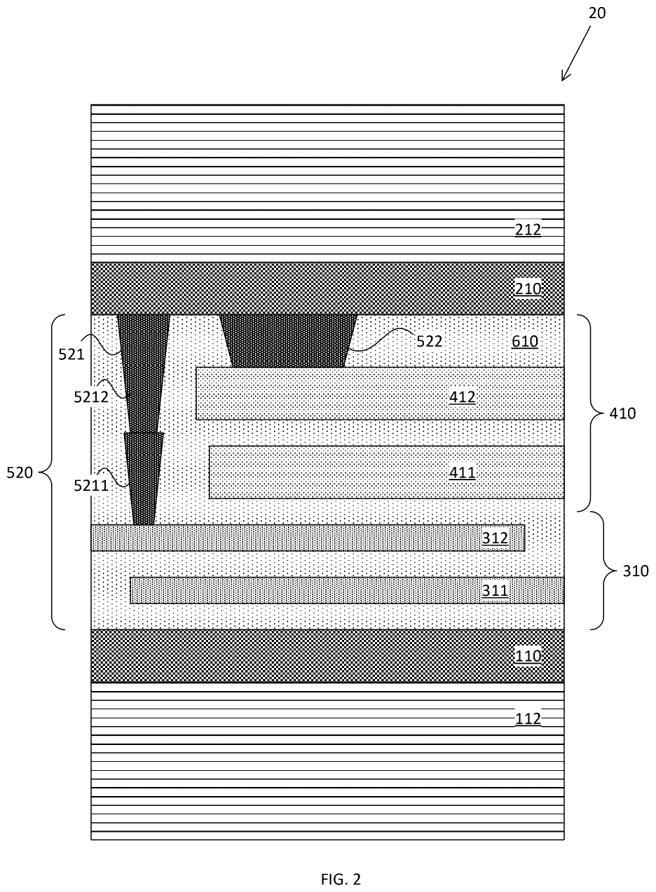

FIG. 2 is a demonstrative illustration of cross-sectional view of a semiconductor structure according to another embodiment of present invention. More specifically, embodiments of present invention provide a semiconductor structure 20 that includes, similar to the semiconductor structure 10 described above with reference to FIG. 1, a first device layer 110 on top of a backside BEOL structure 112; a middle BEOL structure 520 on top of the first device layer 110; a second device layer 210 on top of the middle BEOL structure 520; and a frontside BEOL structure 212 on top of the second device layer 210.

Like the middle BEOL structure 510 illustrated in FIG. 1, the middle BEOL structure 520 may include multiple layers of small pitch wires 310 and multiple layers of large pitch wires 410. Unlike the middle BEOL structure 510, the middle BEOL structure 520 may include one or more first type via connections such as a first type via connection 521. The first type via connection 521 may be made of or include two or more stacked sections with each section being a sub-via. For example, the first type via connection 521 may include a first section 5211 and a second section 5212 on top of the first section 5211. In one embodiment, the second section 5212 may be formed longer or deeper than the first section 5211. The middle BEOL structure 520 may also include one or more second type via connections such as a second type via connection 522, similar to the second type via connection 512 illustrated in FIG. 1.

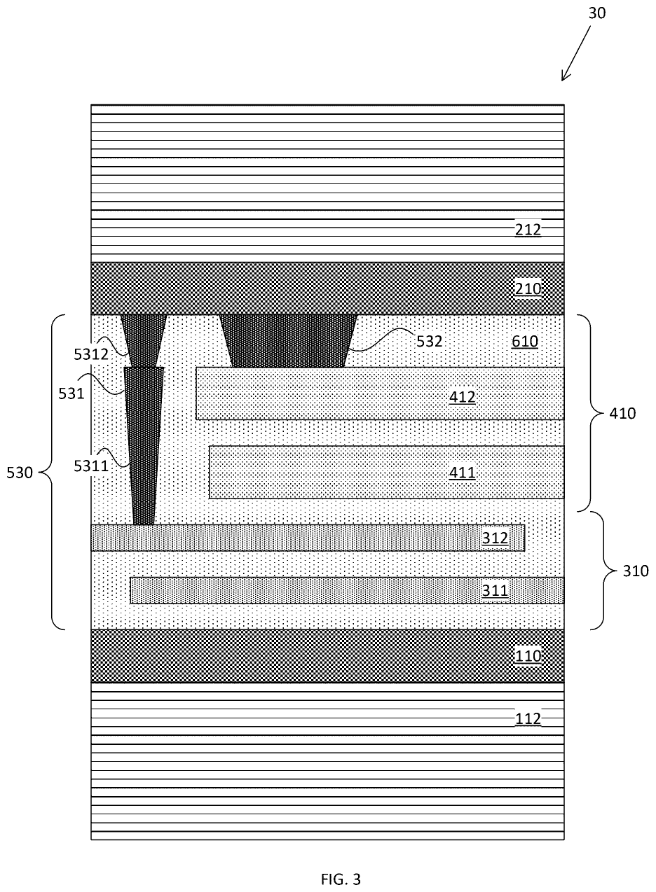

FIG. 3 is a demonstrative illustration of cross-sectional view of a semiconductor structure according to another embodiment of present invention. More specifically, embodiments of present invention provide a semiconductor structure 30 that includes, similar to the semiconductor structure 20 described above with reference to FIG. 2, a first device layer 110 on top of a backside BEOL structure 112; a middle BEOL structure 530 on top of the first device layer 110; a second device layer 210 on top of the middle BEOL structure 520; and a frontside BEOL structure 212 on top of the second device layer 210.

Like the middle BEOL structure 520 illustrated in FIG. 2, the middle BEOL structure 530 may include multiple layers of small pitch wires 310 and multiple layers of large pitch wires 410 and may include one or more first type via connections such as a first type via connection 531. The first type via connection 531 may be made of or include two or more stacked sections with each section being a sub-via. For example, the first type via connection 531 may include a first section 5311 and a second section 5312 on top of the first section 5211. Unlike the first type via connection 521 in FIG. 2, in the embodiment illustrated in FIG. 3, the second section 5312 of the first type via connection 531 may be formed to be shorter or shallower than the first section 5311 of the first type via connection 531.

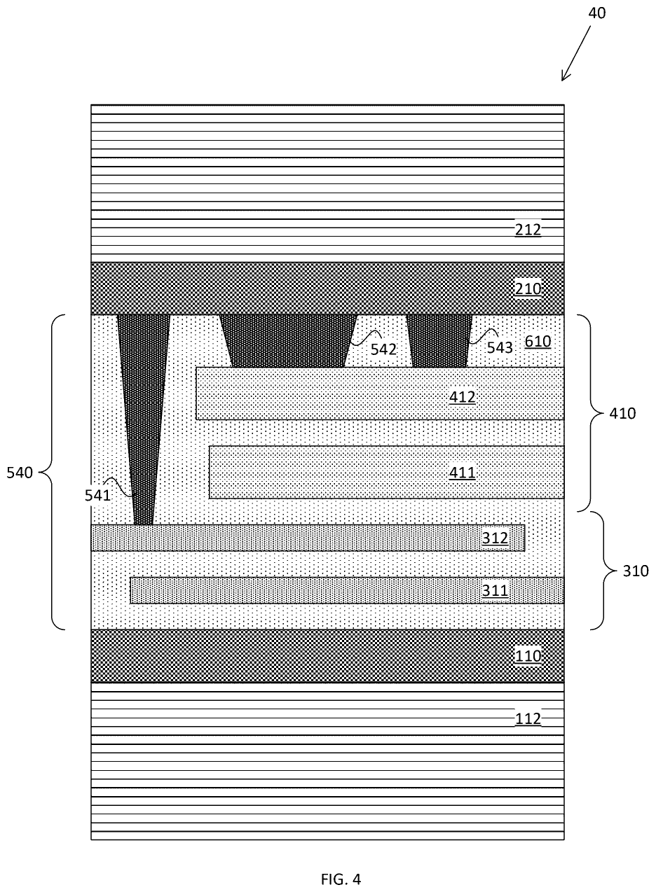

FIG. 4 is a demonstrative illustration of cross-sectional view of a semiconductor structure according to another embodiment of present invention. More specifically, embodiments of present invention provide a semiconductor structure 40 that includes, similar to the semiconductor structure 10 described above with reference to FIG. 1, a first device layer 110 on top of a backside BEOL structure 112; a middle BEOL structure 540 on top of the first device layer 110; a second device layer 210 on top of the middle BEOL structure 540; and a frontside BEOL structure 212 on top of the second device layer 210.

Like the middle BEOL structure 510 illustrated in FIG. 1, the middle BEOL structure 540 may include multiple layers of small pitch wires 310, multiple layers of large pitch wires 410, one or more first type via connections such as a first type via connection 541, and one or more second type via connections such as a second type via connection 542. Unlike the middle BEOL structure 510, the middle BEOL structure 540 may include one or more third type via connections such as a third type via connection 543. The third type via connection 543 may have an aspect ratio greater than two times the aspect ratio of the second type via connection 542, but less than the aspect ratio of the first type via connection 541.

FIGS. 5A-5H are demonstrative illustrations of cross-sectional views of a semiconductor structure at different steps of manufacturing thereof according to embodiments of present invention. More particularly, embodiments of present invention provide a method of forming a semiconductor structure 50 that includes, as is illustrated in FIG. 5A, providing or receiving a semiconductor substrate 109, or a supporting structure, and forming a first device layer 100 on top of the semiconductor substrate 109. The first device layer 100 may include, for example, one or more FETs such as one or more nanosheet FETs. The one or more FETs may be formed in a single layer or formed in stacks to have multiple layers.

Next, as is illustrated in FIG. 5B, embodiments of present invention provide forming a middle BEOL structure 500 in a dielectric layer 600 on top of the first device layer 100. In forming the middle BEOL structure 500, embodiments of present invention provide forming multiple layers of small pitch wires 300 such as a first layer of small pitch wires 301 and a second layer of small pitch wires 302 and forming multiple layers of large pitch wires 400 such as a first layer of large pitch wires 401 and a second layer of large pitch wires 402. The multiple layers of small pitch wires 300 and large pitch wires 400 may be formed in the dielectric layer 600. One or more vias (not shown) may be formed between different layers of the small pitch wires 300, between different layers of the large pitch wires 400, and between the small pitch wires 300 and the large pitch wires 400.

Subsequently, as is illustrated in FIG. 5C, embodiments of present invention provide forming a second device layer 200 on top of the dielectric layer 600 above the middle BEOL structure 500 and forming one or more via connections of several types in the dielectric layer 600. In one embodiment, the second device layer 200 may be, for example, a thin silicon layer and may be bonded onto dielectric layer 600. Active devices may subsequently be formed in the silicon layer of the second device layer 200. Before and/or forming the second device layer 200, one or more via connections may be formed to connect the second device layer 200 with one or more layers of the small pitch wires such as the first layer of small pitch wire 301 and/or the second layer of small pitch wires 302. The one or more via connections may also connect the second device layer 200 with one or more layers of the large pitch wires such as the first layer of large pitch wires 401 and/or the second layer of large pitch wires 402.

More specifically, for example, embodiments of present invention may form a first type via connection 501, in the dielectric layer 600, between the second device layer 200 and the second layer of small pitch wires 302. The first type via connection 501 may have a width W1 and a depth D1 thereby having an aspect ratio of D1/W1. Embodiments of present invention may also form a second type via connection 502, in the dielectric layer 600, between the second device layer 200 and the second layer of large pitch wires 402. The second type via connection 502 may have a width W2 and a depth D2 thereby having an aspect ratio of D2/W2. In one embodiment, the aspect ratio D1/W1 of the first type via connection 501 may be greater than four times the aspect ratio D2/W2 of the second type via connection 502. A high aspect ratio via connection, such as the first type via connection, becomes necessary because it needs to reach a portion of the middle BEOL structure 500 far away from the second device layer 200.

In the meantime, a low aspect ratio via connection, such as the second type via connection 502, may be needed to connect the second device layer 200 to one of the large pitch wires in an upper portion of the middle BEOL structure 500 such as one in the second layer of large pitch wires 402 of the multiple layers of large pitch wires 400. In one embodiment, the second type via connection 502 may be made to have a width W2 that is sufficiently large to accommodate large current for power supply purpose.

As is illustrated in FIG. 5D, embodiments of present invention provide further proceeding to form a frontside BEOL structure 202 on top of the second device layer 200. The frontside BEOL structure 202 may include various interconnects, signal routing structures, and/or various contacts to the second device layer 200. Next, a handling wafer 204 may be attached or bonded to the frontside BEOL structure 202, as is illustrated in FIG. 5E, and the handling wafer 204 may be used in flipping the semiconductor structure 50 upside-down for further processing from a backside thereof.

As is illustrated in FIG. 5F, the semiconductor substrate 109 may then be selectively removed through, for example, a grinding process, a chemical-mechanical-polishing (CMP) process, and/or a combination of other suitable selective etch processes. The removal of the semiconductor substrate 109 exposes a bottom surface of the first device layer 100 for further processing. For example, as is illustrated in FIG. 5G, a backside BEOL structure 102 may be formed on top of the bottom surface of the first device layer 100. In one embodiment, the backside BEOL structure 102 may be a backside power distribution network (BSPDN), which includes various interconnects for power supplies and signal routing for at least the first device layer 100. In some embodiments, source/drain contacts, gate contacts, and backside power rails (BSPRs) may also be included in the backside BEOL structure 102. After forming the backside BEOL structure 102, as is illustrated in FIG. 5H, the handling wafer 204 may be removed from the top of the frontside BEOL structure 202. The removal of the handling wafer 204 may be made through, for example, a CMP process and/or other selective etch process.

FIGS. 6A-6C are demonstrative illustrations of cross-section views of a semiconductor structure according to one embodiment of present invention. More particularly, FIG. 6A is a cross-sectional view of the middle BEOL structure 500 as was discussed with reference to FIG. 5B, FIG. 6B is a first top view, made at a first cross-section as is indicated by the dashed line X1-X1 in FIG. 6A, and FIG. 6C is a second top view, made at a second cross-section as is indicated by the dashed line X2-X2.

More particularly, the multiple layers of small pitch wires 300, such as the first layer of small pitch wire 301, may have a first height H1 and the multiple layers of large pitch wires 400, such as the first layer of large pitch wires 401, may have a second height H2. In one embodiment, the second height H2 may be greater than three times the first height H1. As is illustrated in FIG. 6B, a layer of large pitch wires, such as the second layer of large pitch wires 402, may include multiple large pitch wires such as large pitch wires 4021, 4022, and 4023. The multiple large pitch wires 4021, 4022, and 4023 may have a pitch P2. Also, as is illustrated in FIG. 6C, a layer of small pitch wires, such as the second layer of small pitch wires 302, may include multiple small pitch wires such as small pitch wires 3021, 3022, 3023, 3024, and 3025. The multiple small pitch wires 3021-3025 may have a pitch P1 that is smaller than the pitch P2 of the large pitch wires. In one embodiment, the pitch P2 of the large pitch wires may be greater than three times the pitch P1 of the small pitch wires.

Having the second height H2 being greater than three times the first height H1 and/or having the pitch P2 being greater than three times the pitch P1 are important and sometimes may amount to be critical in ensuring proper performance of the middle BEOL structure 500. For example, while the tight or small pitch wires 3021, 3022, 3023, 3024 and 3025 have small run lengths and may be critical in enabling high density of circuitry where active devices are tightly packed, the wide or large pitch wires 4021, 4022, and 4023 provide low resistance paths for long run lengths in circuit-to-circuit bussing and power distribution.

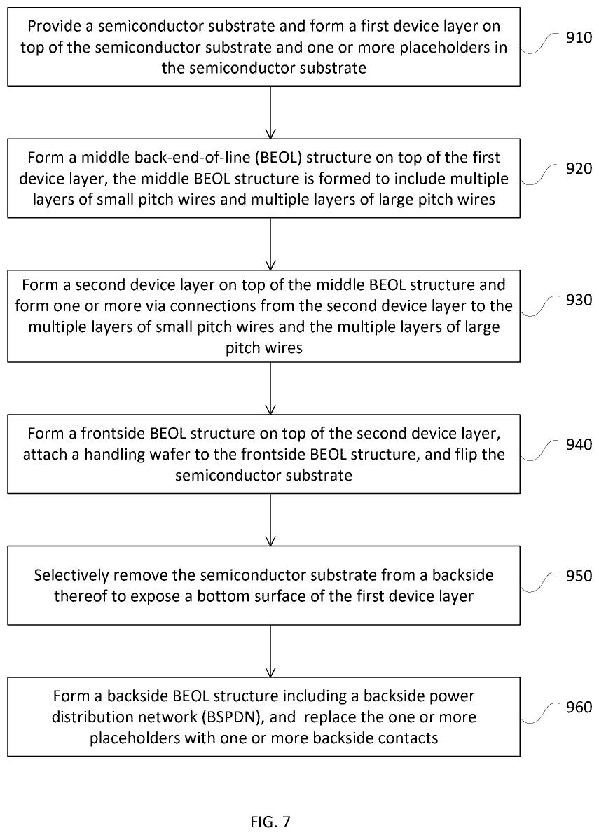

FIG. 7 is a demonstrative illustration of a flow-chart of a method of manufacturing a semiconductor structure according to embodiments of present invention. The method includes (910) providing or receiving a semiconductor substrate, forming a first device layer on top of the semiconductor substrate, and forming one or more placeholders in the semiconductor substrate; (920) forming a middle back-end-of-line (BEOL) structure on top of the first device layer, the middle BEOL structure is formed to include multiple layers of small pitch wires and multiple layers of large pitch wires; (930) forming a second device layer on top of the middle BEOL structure and forming one or more via connections from the second device layer to the multiple layers of small pitch wires and the multiple layers of large pitch wires; (940) forming a frontside BEOL structure on top of the second device layer, attaching a handling wafer to the frontside BEOL structure, and flipping the semiconductor substrate; (950) selectively removing the semiconductor substrate from a backside thereof to expose a bottom surface of the first device layer; and (960) forming a backside BEOL structure including a backside power distribution network (BSPDN), and replacing the one or more placeholders with one or more backside contacts.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A semiconductor structure comprising:
a first device layer on top of a backside back-end-of-line (BEOL) structure;
a middle BEOL structure on top of the first device layer;
a second device layer on top of the middle BEOL structure; and
a frontside BEOL structure on top of the second device layer,
wherein the middle BEOL structure includes multiple layers of small pitch wires; multiple layers of large pitch wires on top of the multiple layers of small pitch wires; and a first type via connection from the second device layer to the multiple layers of small pitch wires.

2. The semiconductor structure of claim 1, wherein a pitch of the large pitch wires is greater than three times a pitch of the small pitch wires.

3. The semiconductor structure of claim 1, wherein a height of one of the large pitch wires is greater than three times a height of one of the small pitch wires.

4. The semiconductor structure of claim 1, wherein the first type via connection is a continuous via.

5. The semiconductor structure of claim 1, wherein the first type via connection is a stacked via made of at least two connected vias.

6. The semiconductor structure of claim 1, further comprising a second type via connection from the second device layer to the multiple layers of large pitch wires.

7. The semiconductor structure of claim 6, wherein the first type via connection has an aspect ratio that is greater than four times an aspect ratio of the second type via connection.

8. The semiconductor structure of claim 6, further comprising a third type via connection from the second device layer to the multiple layers of large pitch wires, wherein the third type via connection has an aspect ratio that is greater than two times the aspect ratio of the second type via connection.

9. The semiconductor structure of claim 8, wherein the second type via connection and the third type via connection have a substantially same height.

10. The semiconductor structure of claim 8, wherein the first type, the second type, and the third type via connection are made of a metal different from a material of the middle BEOL structure.

11. A method of forming a semiconductor structure comprising:
forming a first device layer on top of a substrate;
forming a middle back-end-of-line (BEOL) structure on top of the first device layer;
forming a second device layer on top of the middle BEOL structure;
forming a frontside BEOL structure on top of the second device layer;
attaching a handling wafer onto the frontside BEOL structure and flipping the substrate upside-down;
removing the substrate to expose a bottom surface of the first device layer; and
forming a backside BEOL structure on top of the bottom surface of the first device layer.

12. The method of claim 11, wherein forming the middle BEOL structure comprises:
forming multiple layers of small pitch wires on top of the first device layer; and
forming multiple layers of large pitch wires on top of the multiple layers of small pitch wires.

13. The method of claim 12, wherein forming the second device layer further comprises forming one or more first type via connections connecting the second device layer to the multiple layers of small pitch wires; and forming one or more second type via connections connecting the second device layer to the multiple layers of large pitch wires.

14. The method of claim 13, wherein the one or more first type via connections are made to have an aspect ratio that is greater than four times an aspect ratio of the one or more second type via connections.

15. The method of claim 13, wherein forming the second device layer further comprises forming one or more third type via connections connecting the second device layer to the multiple layers of large pitch wires, wherein the one or more third type via connections are made to have an aspect ratio that is greater than two times the aspect ratio of the one or more second type via connections.

16. The method of claim 13, wherein the one or more first type, one or more second type, and one or more third type via connections are made of a metal different from a material of the middle BEOL structure.

17. The method of claim 11, further comprising forming one or more placeholders in the substrate before forming the middle BEOL structure and replacing the one or more placeholders with one or more backside contacts.

18. A semiconductor structure comprising:
a first device layer on top of a backside back-end-of-line (BEOL) structure;
a middle BEOL structure on top of the first device layer, the middle BEOL structure including multiple layers of small pitch wires and multiple layers of large pitch wires on top of the multiple layers of small pitch wires;
a second device layer on top of the middle BEOL structure;
a frontside BEOL structure on top of the second device layer;
a first type via connection from the second device layer to the multiple layers of small pitch wires; and
a second type and a third type via connection form the second device layer to the multiple layers of large pitch wires.

19. The semiconductor structure of claim 18, wherein the first type via connection has an aspect ratio greater than four times an aspect ratio of the second type via connection.

20. The semiconductor structure of claim 18, wherein the backside BEOL structure is a backside power distribution network (BSPDN).
